(19) United States
(12) Patent Application Publication
(10) Pub. No.: US 2023/0260912 A1
(43) Pub. Date: Aug. 17, 2023

(54) SEMICONDUCTOR STRUCTURE AND METHOD FOR MANUFACTURING THE SAME

(71) Applicant: MACRONIX INTERNATIONAL CO., LTD., Hsinchu (TW)

(72) Inventors: Ting-Feng LIAO, Hsin-chu (TW); Mao-Yuan WENG, Hualien City (TW); Kuang-Wen LIU, Hsin-chu (TW)

(21) Appl. No.: 17/670,561

(22) Filed: Feb. 14, 2022

(51) Int. Cl. H01L 23/535; H01L 27/11582

(52) U.S. Cl. CPC H01L 23/535; H01L 27/11582

(57) ABSTRACT

A semiconductor structure and a method for manufacturing the same are provided. The semiconductor structure includes a conductive pillar having a sidewall and a multi-layer isolation structure on the sidewall of the conductive pillar. The multi-layer isolation structure includes a first isolation layer and a second isolation layer. The first isolation layer is between the conductive pillar and the second isolation layer. The first isolation layer includes protrusions extending toward the second isolation layer. A density of the first isolation layer is different from that of the second isolation layer.

### BACKGROUND

### Technical Field

The disclosure relates to a semiconductor structure and a method for manufacturing the same, and more particularly to a semiconductor structure including multi-layer isolation structure and a method for manufacturing the same.

### Description of the Related Art

With development of the semiconductor technology, semiconductor structures have become smaller in size. However, the interference between components in the semiconductor structure increases as the size of semiconductor structure decrease, which may weaken electrical performance of the semiconductor structure. In order to meet the demand for more powerful, economical and reliable semiconductor structures, it is important to shrink semiconductor structures in size and also to maintain the electricity of semiconductor structures.

It is desirable to provide technology for a semiconductor structure with an improved electrical performance.

### SUMMARY

The present disclosure relates to a semiconductor structure and a method for manufacturing the same.

According to an embodiment of the present disclosure, a semiconductor structure is provided. The semiconductor structure includes a conductive pillar having a sidewall and a multi-layer isolation structure disposed on the sidewall of the conductive pillar. The multi-layer isolation structure includes a first isolation layer and a second isolation layer. The first isolation layer is between the conductive pillar and the second isolation layer. The first isolation layer includes protrusions extending toward the second isolation layer. A density of the first isolation layer is different from a density of the second isolation layer.

According to an embodiment of the present disclosure, a semiconductor structure is provided. The semiconductor structure includes a conductive pillar having a sidewall and a multi-layer isolation structure disposed on the sidewall of the conductive pillar and including N isolation layers, wherein N is one of a positive integer greater than or equal to 3. The isolation layers include a first isolation layer to a N^{th} isolation layer arranged sequentially along a direction away from the conductive pillar. A density of the first isolation layer is less than the densities of the other isolation layers of the isolation layers.

According to an embodiment of the present disclosure, a method for manufacturing a semiconductor structure is provided. The method includes forming a stack structure and forming a multi-layer isolation structure in the stack structure. The step of forming a multi-layer isolation structure in the stack structure includes forming a second isolation layer in the stack structure through a deposition process and an etching process, and forming a first isolation layer on the second isolation layer through another deposition process.

The above and other embodiments of the disclosure will become better understood with regard to the following detailed description of the non-limiting embodiment(s). The following description is made with reference to the accompanying drawings.

### BRIEF DESCRIPTION OF THE DRAWINGS

FIG. 1 schematically illustrates a semiconductor structure according to an embodiment of the present disclosure.

FIG. 2 schematically illustrates a semiconductor structure according to another embodiment of the present disclosure.

FIGS. 3-16 schematically illustrate a method for manufacturing a semiconductor structure according to an embodiment of the present disclosure.

### DETAILED DESCRIPTION

Various embodiments will be described more fully hereinafter with reference to accompanying drawings, which are provided for illustrative and explaining purposes rather than a limiting purpose. For clarity, the components may not be drawn to scale. In addition, some components and/or reference numerals may be omitted from some drawings. It is contemplated that the elements and features of one embodiment can be beneficially incorporated in another embodiment without further recitation.

The embodiments of the present disclosure could be implemented in many different 3D stacked semiconductor structures in the applications. For example, the embodiment could be applied to, but not limited to, the 3D vertical-channel (VC) NAND memory devices or other types of memory device.

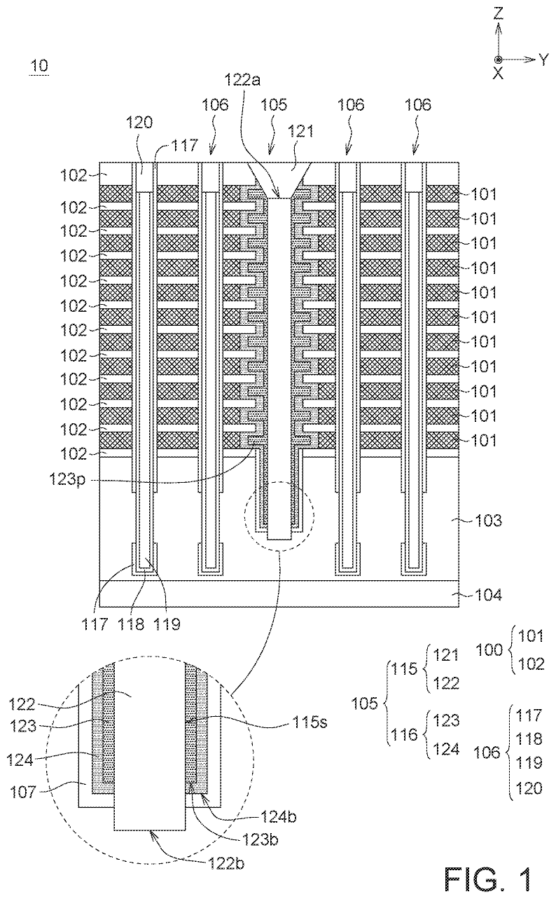

FIG. 1 schematically illustrates a semiconductor structure 10 according to an embodiment of the present disclosure. The semiconductor structure 10 may include a stack structure 100, a semiconductor layer 103, a semiconductor device 104, at least one pillar element 105 and at least one channel structure 106.

The stack structure 100 may include conductive layers 101 and insulating layers 102 stacked alternately along a Z direction. The conductive layers 101 and the insulating layers 102 may extend along an X direction and/or a Y direction. The X direction, the Y direction and Z direction are orthogonal to each other. The insulating layers 102 are separated from each other by the conductive layers 101.

The semiconductor layer 103 may be under the stack structure 100. The semiconductor device 104 may be under the semiconductor layer 103. In an embodiment, the stack structure 100, the semiconductor layer 103 and the semiconductor device 104 may overlap in the Z direction. The semiconductor device 104 may include an active device and/or a passive device. For example, the active device may include a transistor, a diode, and so on. The transistor may include N-type metal-oxide-semiconductor field-Effect transistor (NMOS), P-type metal-oxide-semiconductor field-effect transistor (PMOS), complementary metal-oxide-semiconductor field-effect transistor (CMOS), bipolar junction transistor (BJT), and so on. The passive device may include a resistor, a capacitor and/or an inductor.

At least one pillar element 105 and at least one channel structure 106 are arranged apart in the stack structure 100 and the semiconductor layer 103. The pillar element 105 may include a conductive pillar 115 having a sidewall 115s and a multi-layer isolation structure 116 disposed on the sidewall 115s of the conductive pillar 115. The conductive pillar 115 may extend along the Z direction and penetrate the stack structure 100. The conductive pillar 115 may be electrically connected to the semiconductor layer 103.

The conductive pillar 115 may include an upper conductive portion 121 and a lower conductive portion 122 under the upper conductive portion 121. In an embodiment, the upper conductive portion 121 may taper downwards along the Z direction. In an embodiment, the upper conductive portion 121 may have a lateral cross-sectional area (e.g. a cross-sectional area in the X-Y plane) getting smaller from a top surface of the upper conductive portion 121 to a bottom surface of the upper conductive portion 121 along the Z direction. The present disclosure is not limited thereto. The upper conductive portion 121 may have other suitable shapes. The lower conductive portion 122 may extend along the Z direction and penetrate the stack structure 100. The lower conductive portion 122 may include an upper end 122a connecting to the upper conductive portion 121 and a lower end 122b opposite to the upper end 122a. The upper end 122a of the lower conductive portion 122 is in the stack structure 100. The lower end 122b of the lower conductive portion 122 is under the stack structure 100 and in the semiconductor layer 103.

The multi-layer isolation structure 116 may penetrate the stack structure 100. The multi-layer isolation structure 116 may include a first isolation layer 123 and a second isolation layer 124. The first isolation layer 123 is between the conductive pillar 115 and the second isolation layer 124. The lower end 122b of the lower conductive portion 122 may be under a bottom surface 124b of the second isolation layer 124. The bottom surface 124b of the second isolation layer 124 may be under a bottom surface 123b of the first isolation layer 123. The first isolation layer 123 may include protrusions 123p disposed apart. The protrusions 123p may extend laterally toward the second isolation layer 124. Each of the protrusions 123p of the first isolation layer 123 may be disposed between the insulating layers 102 of the stack structure 100. The protrusions 123p of the first isolation layer 123 may correspond to the conductive layers 101 of the stack structure 100. For example, the positions of the protrusions 123p in the Z direction (e.g. levels) may correspond to the conductive layers 101 respectively, and each of the protrusions 123p may extend laterally toward the corresponding conductive layer 101.

In an embodiment, the first isolation layer 123 may have a density different from a density of the second isolation layer 124. For example, the density of the first isolation layer 123 may be less than the density of the second isolation layer 124.

The channel structure 106 may extend along the Z direction and penetrate the stack structure 100. The channel structure 106 may have a lower channel end 106b. The lower channel end 106b of the channel structure 106 may be under the bottom surface 124b of the second isolation layer 124 and/or under the lower end 122b of the lower conductive portion 122. The channel structure 106 may include a memory film 117, a vertical channel film 118, an insulating pillar 119 and a pad 120. The memory film 117 may surround the vertical channel film 118. In an embodiment, the memory film 117 may surround part of the vertical channel film 118. For example, as shown in FIG. 1 in the semiconductor layer 103, a part of the vertical channel film 118 is not surrounded by the memory film 117; electric current may flow between the channel structure 106 and the semiconductor layer 103 through this part. The channel structure 106 may electrically connect to the semiconductor layer 103, and electrically connect to the conductive pillar 115. The vertical channel film 118 is between the memory film 117 and the insulating pillar 119. The vertical channel film 118 may have a tubular shape and surround the insulating pillar 119. In an embodiment, the vertical channel film 118 may have a tubular shape with one closed end and one open end. The pad 120 is on the vertical channel film 118 and the insulating pillar 119, and may be surrounded by the memory film 117. The d vertical channel film 118 may be functioned as providing a channel for electrons or electron holes when applying a voltage to the semiconductor structure 10.

The semiconductor structure 10 may include memory cells disposed in the stack structure 100. The memory cells may be defined in the memory film 117 at intersections between the conductive layers 101 and the vertical channel film 118 of the channel structure 106.

The semiconductor structure 10 may further include a protection layer 107 disposed between the multi-layer isolation structure 116 and the semiconductor layer 103.

In an embodiment, the conductive layers 101 may be functioned as word lines (WLs), and the conductive pillar 115 may be functioned as a source line (SL) such as a common source line.

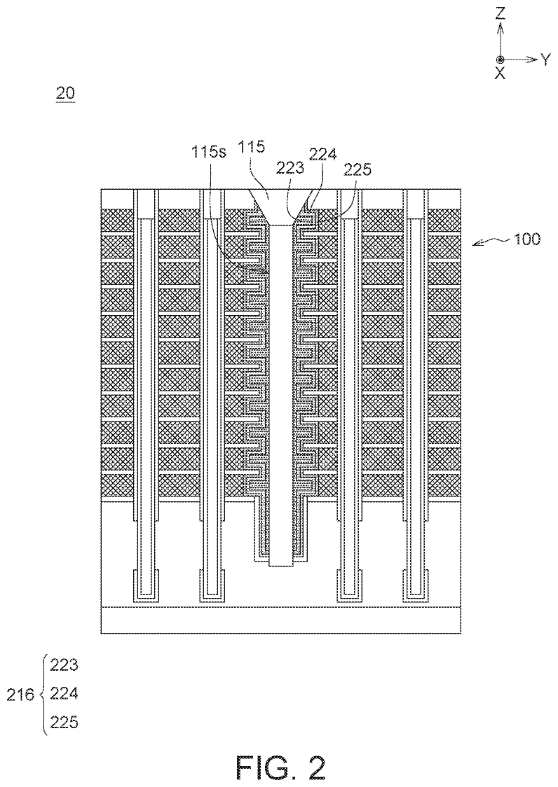

As shown in FIG. 1, the semiconductor structure 10 includes two isolation layers (the first isolation layer 123 and the second isolation layer 124). The present disclosure is not limited thereto. The present disclosure can be applied to the semiconductor structure including two or more isolation layers. In an embodiment, the present disclosure can be applied to the semiconductor structure including three isolation layers, as the semiconductor structure 20 exemplarily shown in FIG. 2.

In FIG. 2, the semiconductor structure 20 may include at least one pillar element 205 in the stack structure 100. The pillar element 205 may include a conductive pillar 115 having a sidewall 115s and a multi-layer isolation structure 216 disposed on the sidewall 115s of the conductive pillar 115. The multi-layer isolation structure 216 may include a first isolation layer 223, a second isolation layer 224 and a third isolation layer 225. The first isolation layer 223 is between the conductive pillar 115 and the second isolation layer 224. The second isolation layer 224 is between the first isolation layer 223 and the third isolation layer 225. The first isolation layer 223 may be similar to the first isolation layer 123 of the semiconductor structure 10. The second isolation layer 224 may be similar to the second isolation layer 124 of the semiconductor structure 10. In an embodiment, the first isolation layer 223 may have a density different from a density of the second isolation layer 224 and/or a density of the third isolation layer 225. For example, the density of the first isolation layer 223 may be less than the density of the second isolation layer 224, and/or the density of the first isolation layer 223 may be less than the density of the third isolation layer 225.

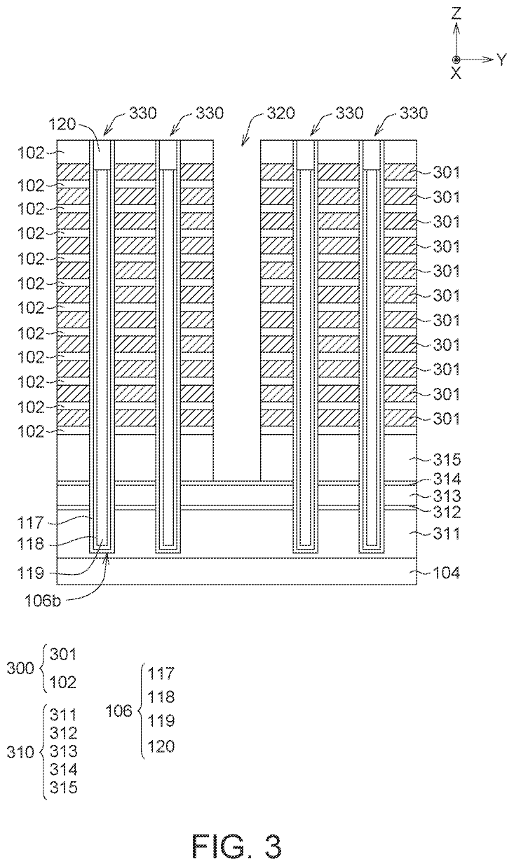

FIGS. 3-16 schematically illustrate a method for manufacturing a semiconductor structure according to an embodiment of the present disclosure.

Referring to FIG. 3, an insulating stack structure 300, a semiconductor material stack 310 and a semiconductor device 104 are provided. The insulating stack structure 300 may be formed on the semiconductor material stack 310. The semiconductor material stack 310 may be formed on the semiconductor device 104.

The semiconductor material stack 310 may include a first semiconductor material layer 311, a first inter-layer insulating layer 312, a second semiconductor material layer 313, a second inter-layer insulating layer 314 and a third semiconductor material layer 315 stacked sequentially from bottom to top along the Z direction. In an embodiment, the first semiconductor material layer 311, the second semiconductor material layer 313 and the third semiconductor material layer 315 may include a doped or undoped semiconductor material, such as doped or undoped polysilicon. The first inter-layer insulating layer 312 and the second inter-layer insulating layer 314 may include insulating materials comprising oxide, such as silicon oxide. In an embodiment, the semiconductor material stack 310 may be formed by depositing the semiconductor material layer 311 the first inter-layer insulating layer 312, the second semiconductor material layer 313, the second inter-layer insulating layer 4 and the third semiconductor material layer 315 sequentially on the semiconductor device 104, for example, by a chemical vapor deposition (CVD) process.

The insulating stack structure 300 may include sacrifice layers 301 and insulating layers 102 stacked alternately along the Z direction. The sacrifice layers 301 and the insulating layers 102 may extend along an X direction and/or a Y direction. The insulating layers 102 are separated from each other by the sacrifice layers 301. In an embodiment, the sacrifice layers 301 of the insulating stack structure 300 may include insulating materials comprising nitride, such as silicon nitride. The insulating layers 102 of the insulating stack structure 300 may include insulating materials comprising oxide, such as silicon oxide. In an embodiment, the sacrifice layer 301 and the insulating layer 102 may include different materials. In an embodiment, the insulating stack structure 300 may be formed by depositing the sacrifice layers 301 and the insulating layers 102 sequentially.

At least one channel structure 106 is formed in the insulating stack structure 300. The channel structure 106 may extend along the Z direction and penetrate the insulating stack structure 300, the third semiconductor material layer 315, the second inter-layer insulating layer 314, the second semiconductor material layer 313 and the first inter-layer insulating layer 312. The lower channel end 106b of the channel structure 106 may be in the first semiconductor material layer 311. The channel structure 106 may include the memory film 117, the vertical channel film 118, the insulating pillar 119 and the pad 120.

The memory film 117 may include a multilayer structure known from memory technologies as ONO (oxide-nitride-oxide), ONONO (oxide-nitride-oxide-nitride-oxide), ONONONO (oxide-nitride-oxide-nitride-oxide-nitride-oxide), SONOS (silicon-oxide-nitride-oxide-silicon), BE-SONOS (bandgap engineered silicon-oxide-nitride-oxide-silicon), TANOS (tantalum nitride, aluminum oxide, silicon nitride, silicon oxide, silicon), MA BE-SONOS (metal-high-k bandgap-engineered silicon-oxide-nitride-oxide-silicon), and combinations of those layers.

The vertical channel film 118 may include a doped or undoped semiconductor material, such as doped or undoped polysilicon. The insulating pillar 119 may include a dielectric material comprising oxide, such as silicon oxide. The pad 120 may include a doped or undoped semiconductor material, such as doped or undoped polysilicon.

In an embodiment, the channel structure 106 may be formed by the following steps: the insulating stack structure 300 is patterned, for example, the insulating stack structure 300 may be patterned by a photolithography process, to form at least one hole 330 in the insulating stack structure 300; the hole 330 may extend down along the Z direction, penetrate the insulating stack structure 300, the third semiconductor material layer 315, the second inter-layer insulating layer 314, the second semiconductor material layer 313 and the first inter-Dyer insulating layer 312 and stop in the first semiconductor material layer 311; the first semiconductor material layer 311 may be considered as an etching stopping layer. Then, the memory film 117, the vertical channel film 118, the insulating pillar 119 and the pad 120 are deposited sequentially in the hole 330 to formed the channel structure 106.

The insulating stack structure 300 is patterned, for example, the insulating stack structure 300 may be patterned by a photolithography process, to form at least one trench 320 in the insulating stack structure 300. The trench 320 may extend down along the Z direction, penetrate the insulating stack structure 300, and stop on the second inter-layer insulating layer 314. The trench 320 exposes sidewalls of the insulating stack structure 300 and the third semiconductor material layer 315 (serving as the side all of the trench 320) and exposes part of the upper surface of the second inter-layer insulating layer 314 (serving as the bottom of the trench 320). In an embodiment, the trench 320 may be formed by two etching steps with different etching selectivity, as illustrated in the following example. A first etching step with lower etching selectivity may be performed to form the trench 320 in the insulating stack structure 300, and the resulting trench 320 extends down along the Z direction, penetrate the insulating stack structure 300, and stop in the third semiconductor material layer 315; the third semiconductor material layer 315 may be considered as an etching stopping layer; part of the third semiconductor material layer 315 can be exposed at the bottom of the resulting trench 320. Then, a second etching step with higher etching selectivity may be performed to extend the trench 320 down along the Z direction, and remove part of the third semiconductor material layer 315 to expose part of the upper surface of the second inter-layer insulating layer 314. The trench 320 as shown in FIG. 3 can be formed. The second etching step with higher etching selectivity is stop on the second inter-layer insulating layer 314. In this embodiment, using two etching steps with different etching selectivity to form the trench 320 helps to accurately control the profile of the trench 320 acutely and ensure that the trench 320 stops at a desired position.

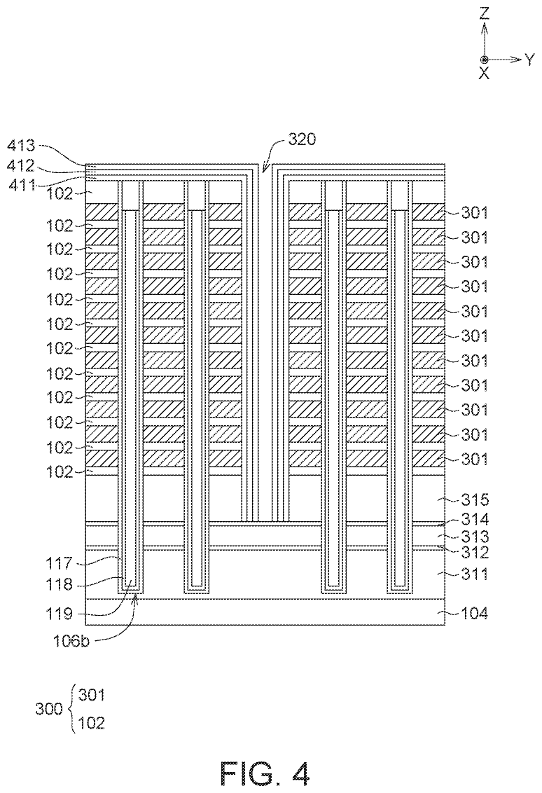

Referring to FIG. 4, an insulating film 411, an insulating film 412 and an insulating film 413 is formed on the sidewall of the trench 320 and the upper surface of the insulating stack structure 300. For example, the insulating film 411 can be formed on the upper surface of the insulating stack structure 300 and line the trench 320 by a deposition process, and part of the insulating film 411 at the bottom of the trench 320 is removed by an etching step; then, the insulating film 412 is formed on the insulating film 411 by a deposition process, and part of the insulating film 412 is removed by an etching step; then, the insulating film 413 is formed on the insulating film 412 by a deposition process, and part of the insulating film 413 is removed by an etching step; after that; part of the second inter-layer insulating layer 314 is exposed at the bottom of the trench 320, The insulating film 411 may include an insulating material comprising nitride, such as silicon nitride. The insulating film 412 may include an insulating material comprising oxide; such as silicon oxide. The insulating film 413 may include an insulating material comprising nitride, such as silicon nitride.

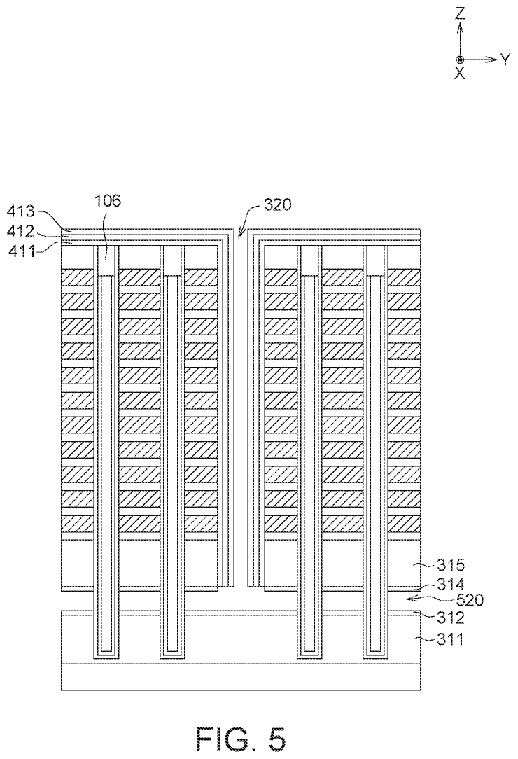

Referring to FIG. 5, part of the second inter-layer insulating layer 314 and the second semiconductor material layer 313 is removed through the trench 320, for example, by an etching step, and a slit 520 is formed. The slit 520 is between the first inter-layer insulating layer 312 and the second inter-layer insulating layer 314. This etching step substantially remove the second semiconductor material layer 313 and doesn't remove the first semiconductor material layer 311 under the first inter-layer insulating layer 312 and third semiconductor material layer 315 above the second inter-layer insulating layer 314. Part of the sidewall of the channel structure 106 is exposed by the slit 520. Specifically, part of the sidewall of the memory film 117 of the channel structure 106 is exposed by the slit 520.

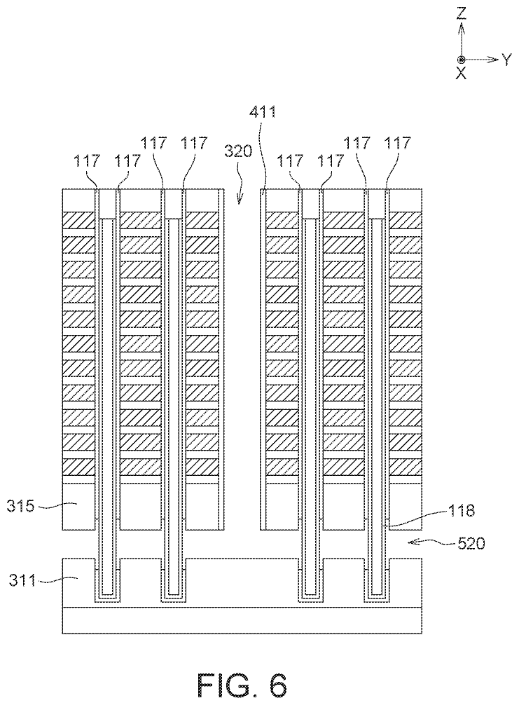

Referring to FIG. 6, the first inter-layer insulating layer 312, the second inter-layer insulating layer 314, the insulating film 412 and the insulating film 413 are removed, for example, by one or more etching steps. In an embodiment, part of the memory film 117 of the channel structure 106 may be removed during the one or more etching steps. In an embodiment, part of the insulating film 411 on the insulating stack structure 300 may be removed, and another part of the insulating film 411 on the sidewall of the trench 320 may be remained. For example, part of the insulating film 411 on the insulating stack structure 300 may be removed by a chemical-mechanical planarization (CMP) and/or an etching step.

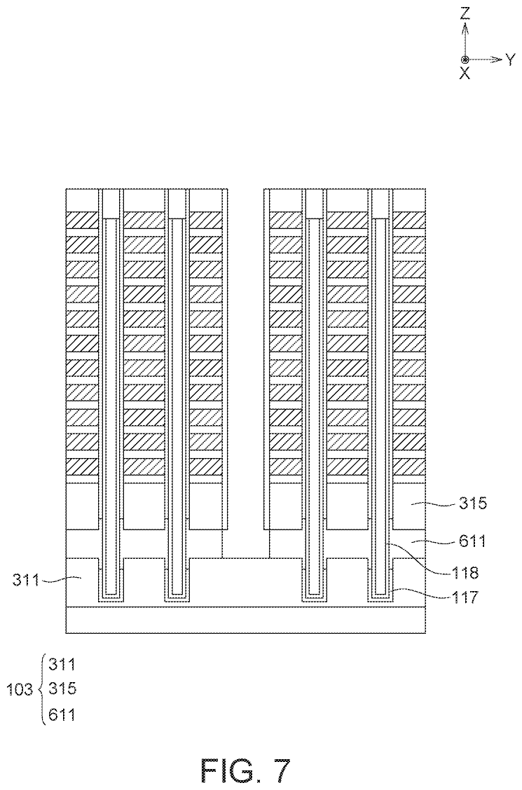

Referring to FIG. 7, a fourth semiconductor material layer 611 is formed between the first semiconductor material layer 311 and the third semiconductor material layer 315, for example, by a deposition process. In an embodiment, the fourth semiconductor material layer 611 may connect or contact the memory film 117, the vertical channel film 118, the first semiconductor material layer 311 and the third semiconductor material layer 315. In an embodiment, the fourth semiconductor material layer 611 may include a doped or undoped semiconductor material, such as doped or undoped polysilicon. The first semiconductor material layer 311, the fourth semiconductor material layer 611 and the third semiconductor material layer 315 form the semiconductor layer 103. The semiconductor layer 103 may include a doped or undoped semiconductor material, such as doped or undoped polysilicon.

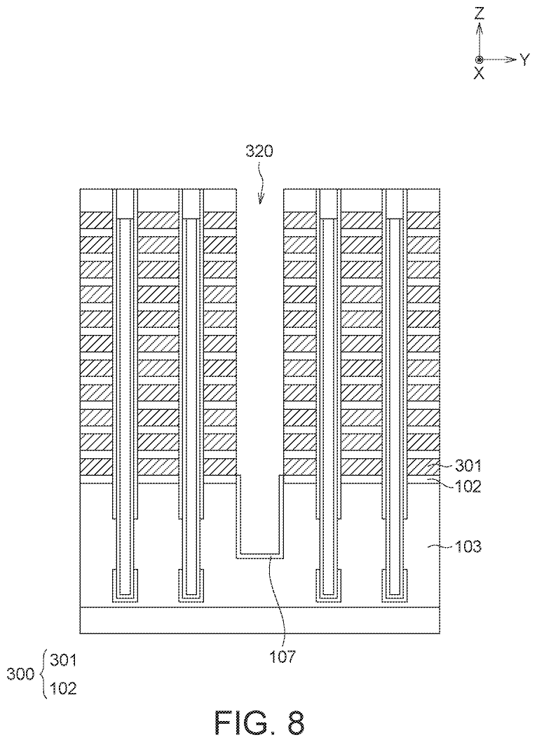

Referring to FIG. 8, the remained insulating film 411 is removed, for example, by an etching step, and a protection layer 107 is formed at the bottom of the trench 320 and on part of the sidewall of the trench 320. The protection layer 107 may cover the semiconductor layer 103 exposed by the trench 320. In an embodiment, the protection layer 107 may cover the sidewall of the bottommost insulating layer 102 of the insulating stack structure 300. In an embodiment, the protection layer 107 may include an insulating material comprising oxide, such as silicon oxide.

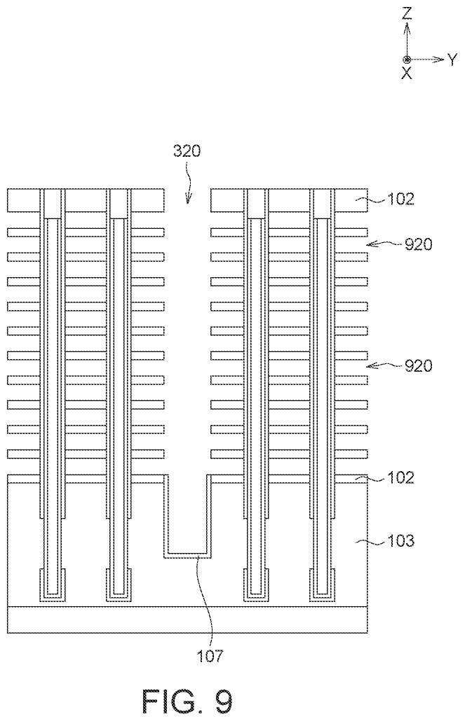

Referring to FIG. 9, the sacrifice layers 301 of the insulating stack structure 300 are removed, for example, by an etching step, and spaces 920 between the insulating layers 102 are formed. In this etching step, the protection layer 107 protects the semiconductor layer 103 and prevents the semiconductor layer 103 from being removed during the etching step. In an embodiment, the etching step may include a wet etching process using hot phosphoric acid (H₃FO₄) or other suitable chemical substances.

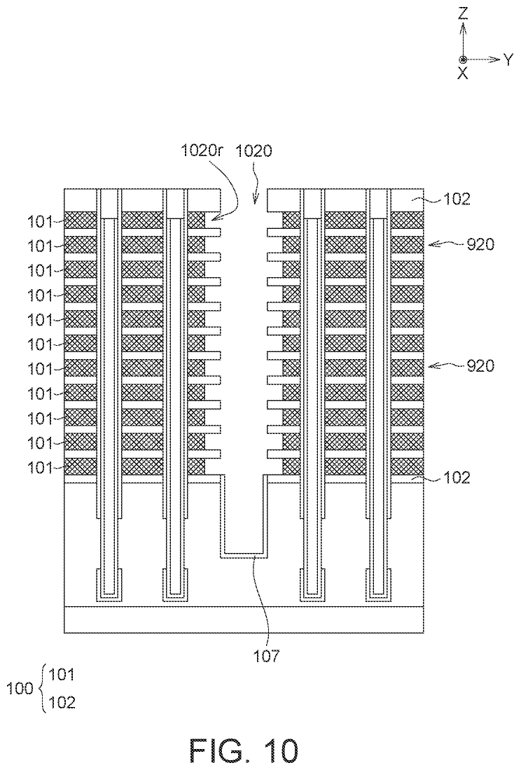

Referring to FIG. 10, the spaces 920 are filled by conductive materials and conductive layers 101 between the insulating layers 102 are formed. In this way, a stack structure 100 and a trench 1020 in the stack structure 100 are formed. The trench 1020 may include recesses 1020r between the insulating layers 102. The recesses 1020r extend into the conductive layers 101 along the X direction and/or the Y direction.

In an embodiment, the processes encompassed in FIGS. 9-10 may be understood as a gate replacement process. In an embodiment, the conductive layers 101 may include conductive materials, such as tungsten (W).

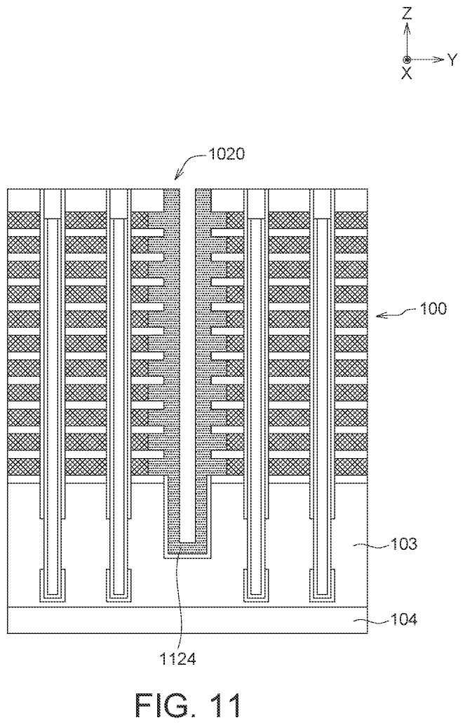

Referring to FIG. 11, an isolation material layer 1124 lines the trench 1020, for example, by a deposition process. The isolation material layer 1124 may cover sidewalls of the conductive layers 101 and insulating layers 102 of the stack structure 100 exposed by the trench 1020. The isolation material layer 1124 may cover the protection layer 107. In an embodiment, the isolation material layer 1124 may include oxide, such as low temperature oxide (LTO).

Referring to AG. 12, a thermal treatment is applied to the isolation material layer 1124, so as to densify the isolation material layer 1124. After the thermal treatment, the isolation material layer 1124 is transform to a densified isolation material layer 1224. In an embodiment, the thermal treatment may be a rapid thermal process (RTP) performed at 800-900° C. for about 25-35 seconds, in an embodiment, the rapid thermal process may be performed at 850° C. for about 30 seconds. The thermal treatment may be understood as a densification process, and the isolation material layer 1124 becomes denser through the thermal treatment. The densified isolation material layer 1224 may be denser than the isolation material layer 1124. A density of the densified isolation material layer 1224 is higher than that of the isolation material layer 1124.

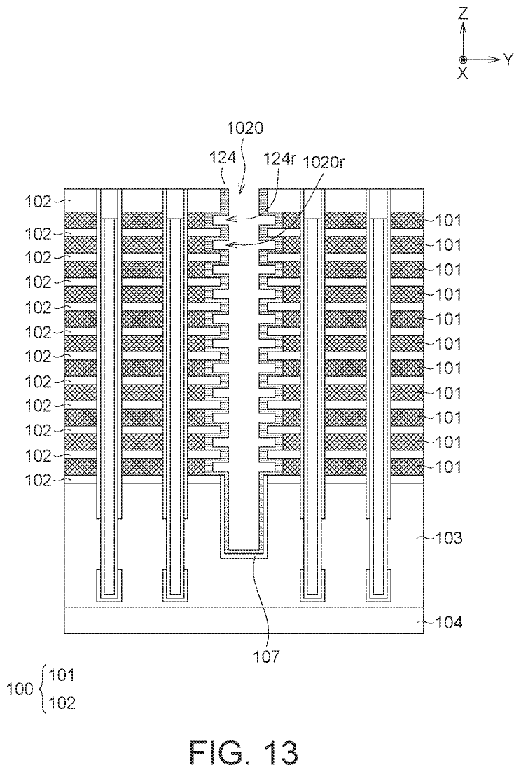

Referring to FIG. 13, an etching step is applied to the densified isolation material layer 1224 and a second isolation layer 124 penetrating the stack structure 100 is formed. In an embodiment, the etching step may remove part of the densified isolation material layer 1224 in the recesses 1020r so as to form the second isolation layer 124 including recesses 124r, The recesses 124r of the second isolation layer 124 may correspond to the conductive layers 101 of the stack structure 100. Each of the recesses 124r may extend laterally toward the corresponding conductive layer 101. In an embodiment, the second isolation layer 124 may include oxide, such as low temperature oxide. In an embodiment, the second isolation layer 124 may include densified or dense low temperature oxide.

In an embodiment, performing the thermal treatment before the etching step helps to reduce the etching rate of the etching step, improve the controllability of the etching and obtain a more accurate etching profile. In another embodiment, performing the thermal treatment to the isolation material layer 1124 is optional, and the second isolation layer 124 may be formed by performing an etching step to the isolation material layer 1124. Whether to perform a thermal treatment to the isolation material layer 1124 may depend on the property of material of the isolation material layer 1124 and/or the design of the semiconductor structure. For example, when the isolation material layer 1124 include a dense material, or the etching rate to the isolation material layer 1124 is slower, performing a thermal treatment to the isolation material layer 1124 can be omitted.

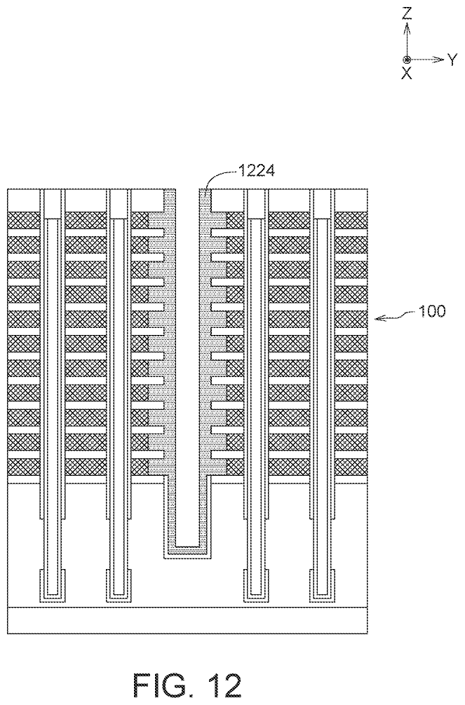

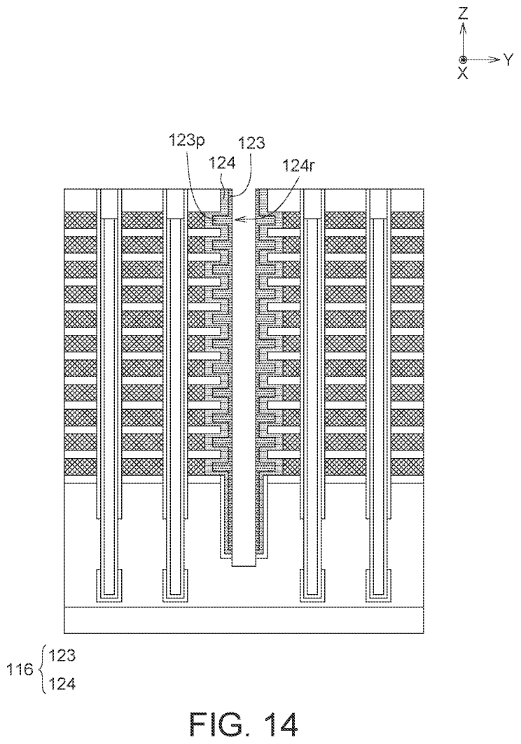

Referring to FIG. 14, a first isolation layer 123 is formed on the second isolation layer 124, for example, by a deposition process. The first isolation layer 123 may penetrate the stack structure 100. A multi-layer isolation structure 116 including the first isolation layer 123 and the second isolation layer 124 is formed. The first isolation layer 123 may include protrusions 123p. The protrusions 123p of the first isolation layer 123 are formed in the recesses 124r of the second isolation layer 124. The density of the first isolation layer 123 can be different from that of the second isolation layer 124, which results in an interface between the first isolation layer 123 and the second isolation layer 124. For example, the density of the first isolation layer 123 may be less than that of the second isolation layer 124. In an embodiment, the formation of the second isolation layer 124 includes a thermal treatment (as shown in FIG. 12), and the thermal treatment makes the second isolation layer 124 denser than the first isolation layer 123. In an embodiment, the first isolation layer 123 may include oxide, such as low temperature oxide.

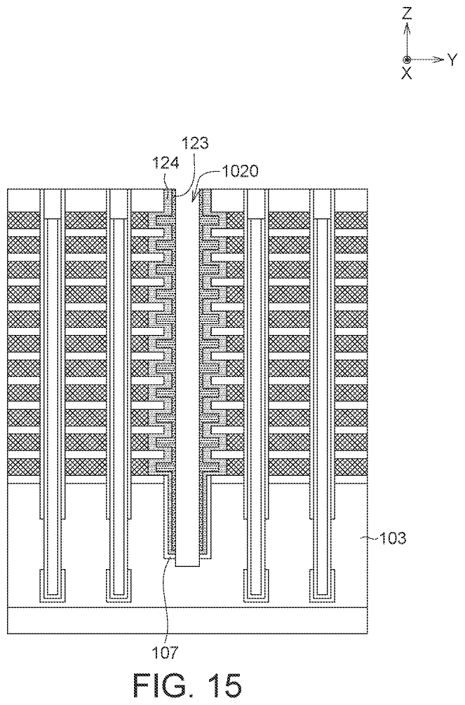

Referring to FIG. 15, part of the first isolation layer 123, part of the second isolation layer 124 and part of the protection layer 107 are removed, for example, by an etching step, and the semiconductor layer 103 is exposed.

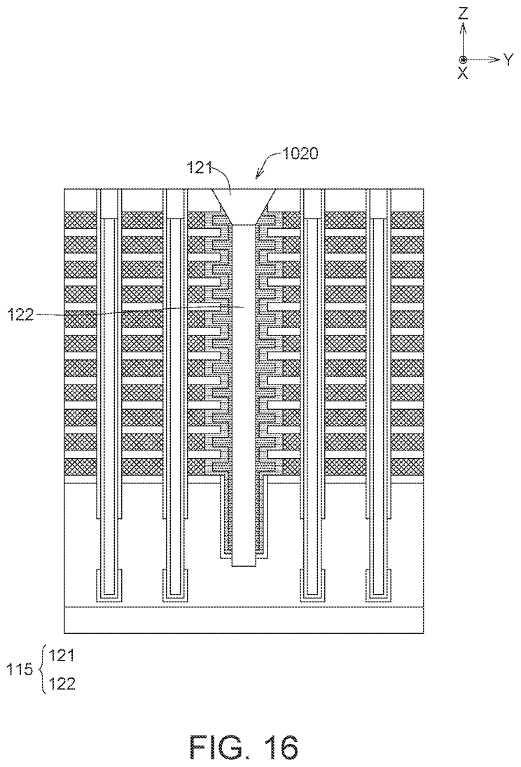

Referring to FIG. 16, a conductive pillar 115 is formed to fill the trench 1020. The formation of the conductive pillar 115 may include the following steps: a lower conductive portion 122 may be formed on the side all of the first isolation layer 123 by a deposition process; an upper conductive portion 121 may be formed on the lower conductive portion 122 by another deposition process. In an embodiment, the formation of the conductive pillar 115 may further include: part of the first isolation layer 123, part of the second isolation layer 124 and/or part of the uppermost insulating layer 102 of the stack structure 100 are removed so that the upper conductive portion 121 tapers downwards along the Z direction. In an embodiment, the upper conductive portion 121 may include a metal material, such as tungsten; the lower conductive portion 122 may include a doped or undoped semiconductor material, such as doped or undoped polysilicon. In another embodiment, both of the upper conductive portion 121 and the lower conductive portion 122 may include metal materials, such as tungsten. In an embodiment, through the method schematically illustrated in FIGS. 3-16, a semiconductor structure is provided, as shown in FIG. 1.

As shown in FIGS. 3-16, the method for manufacturing a semiconductor structure according to the present disclosure can be applied to the semiconductor structure including two isolation layers. The present disclosure is not limited thereto. The present disclosure can be applied to the semiconductor structure including two or more isolation layers. In an embodiment, the present disclosure can be applied to the semiconductor structure including N isolation layers (i.e, the multi-layer isolation structure of the semiconductor structure includes N isolation layers), and N is one of a positive integer greater than or equal to 2.

When N=2, the multi-layer isolation structure of the semiconductor structure includes two isolation layers, the manufacturing method and the resulting semiconductor structure are shown in FIGS. 3-16.

When N=3, the multi-layer isolation structure of the semiconductor structure includes three isolation layers. The difference between the manufacturing method for three isolations and the manufacturing method for two isolations is that, the method includes forming a third isolation layer between the second isolation and the stack structure before the formation of the second isolation layer; the formation of the third isolation layer may be similar to the formation of the second isolation layer. In other words, the formation of the third isolation layer may include depositing an isolation material layer, and applying a thermal treatment and an etching step to the isolation material layer (the thermal treatment is optional). The resulting third isolation layer may be similar to the second isolation layer. The density of the first isolation layer may be less than that of the second isolation layer, and/or the density of the first isolation layer may be less than that of the third isolation layer. The densities of the second isolation layer and the third isolation layer may be the same or different. The third isolation layer may include low temperature oxide or dense low temperature oxide or densified low temperature oxide. The semiconductor structure produced by this manufacturing method can be understood as the semiconductor structure 20 shown in FIG. 2.

When N is one of a positive integer greater than or equal to 3, the multi-layer isolation structure of the semiconductor structure includes N isolation layers. N isolation layers includes a first isolation layer, a second isolation layer . . . a N^{th} isolation layer arranged sequentially along a direction away from the conductive pillar, wherein a density of the first isolation layer is less than the densities of the other isolation layers (i.e. the 2^{nd} isolation layer to N^{th} isolation layer) of the isolation layers. The manufacturing method for this semiconductor structure may include forming a N^{th} isolation layer, a N-1^{th} isolation layer . . . a second isolation layer and a first isolation layer sequentially in the stack structure; the formations of the isolation layers other than the first isolation layer may be similar to the formation of the second isolation layer 124 shown in FIGS. 11-13, and the formation of the first isolation layer may be similar to the formation of the first isolation layer 123 shown in FIG. 14.

In a comparative example, a single-layer isolation structure is used to isolate the conductive pillar and the stack structure of the semiconductor structure. The single-layer isolation structure has a poor filling property, and has voids during the manufacturing process. The voids in the isolation structure will reduce the isolation between the conductive pillar and the stack structure, and reduce the electrical performance of the semiconductor structure. Specifically, the materials of the conductive layers will permeate into the voids of single-layer isolation structure and thereby forming current leakage paths between the conductive pillar and the conductive layers of the stack structure; the current leakage paths will disturb the operation of the semiconductor structure, cause ion current to be difficult to detect, and reduce the electrical performance of the semiconductor structure.

The present disclosure provides a semiconductor structure including multi-layer isolation structure between conductive pillar and the stack structure. As compared with the comparative example using a single-layer isolation structure, the multi-layer isolation structure of the present disclosure has a better filling property and less voids. With such a configuration, the current leakage problem caused by the materials of the conductive layers permeating into the voids can be reduced or solved, ion current can be detect, and the electrical performance and yield of the semiconductor structure can be improved. Moreover, in the multi-layer isolation structure according to the present disclosure, the properties (e.g. densities) and profiles (e.g. the first isolation layer includes protrusions extending toward the corresponding conductive layers, and/or the second isolation layer includes recesses extending toward the corresponding conductive layers) of isolation layers contribute to further improve the filling property. In addition, in the manufacturing method for a semiconductor structure according to the present disclosure, the formation of the multi-layer isolation structure includes steps of deposition, etching and re-deposition, so that a better profile of the isolation layer can be achieved and the voids in the isolation layers can be reduced.

It is noted that the structures and methods as described above are provided for illustration. The disclosure is not limited to the configurations and procedures disclosed above. Other embodiments with different configurations of known elements can be applicable, and the exemplified structures could be adjusted and changed based on the actual needs of the practical applications. It is, of course, noted that the configurations of figures are depicted only for demonstration, not for limitation. Thus, it is known by people skilled in the art that the related elements and layers in a semiconductor structure, the shapes or positional relationship of the elements and the procedure details could be adjusted or changed according to the actual requirements and/or manufacturing steps of the practical applications.

While the disclosure has been described by way of example and in terms of the exemplary embodiment(s), it is to be understood that the disclosure is not limited thereto. On the contrary, it is intended to cover various modifications and similar arrangements and procedures, and the scope of the appended claims therefore should be accorded the broadest interpretation so as to encompass all such modifications and similar arrangements and procedures.

What is claimed is:

1. A semiconductor structure, comprising:
a conductive pillar having a sidewall; and
a multi-layer isolation structure disposed on the sidewall of the conductive pillar and comprising a first isolation layer and a second isolation layer, wherein the first isolation layer is between the conductive pillar and the second isolation layer, the first isolation layer comprises protrusions extending toward the second isolation layer, a density of the first isolation layer is different from a density of the second isolation layer.

2. The semiconductor structure according to claim 1, wherein a bottom surface of the second isolation layer is under a bottom surface of the first isolation layer.

3. The semiconductor structure according to claim 1, wherein the first isolation layer is between the conductive pillar and the second isolation layer, the density of the first isolation layer is less than the density of the second isolation layer.

4. The semiconductor structure according to claim 3, wherein the multi-layer isolation structure further comprises a third isolation layer, the second isolation layer is between the first isolation layer and the third isolation layer, the density of the first isolation layer is less than a density of the third isolation layer.

5. The semiconductor structure according to claim 1, further comprising a stack structure, wherein the multi-layer isolation structure is disposed in the stack structure, the stack structure comprises conductive layers and insulating layers stacked alternately, the protrusions of the first isolation layer correspond to the conductive layers.

6. The semiconductor structure according to claim 5, further comprising a channel structure disposed in the stack structure and a semiconductor layer under the stack structure.

7. The semiconductor structure according to claim 6, wherein the channel structure is electrically connected to the conductive pillar through the semiconductor layer.

8. The semiconductor structure according to claim 6, further comprising a semiconductor device under the semiconductor layer and comprising an active device and/or a passive device.

9. The semiconductor structure according to claim 1, wherein the conductive pillar comprises an upper conductive portion and a lower conductive portion under the upper conductive portion, the upper conductive portion comprises a metal material, the lower conductive portion comprises a semiconductor material.

10. The semiconductor structure according to claim 1, wherein there is an interface between the first isolation layer and the second isolation layer.

11. A semiconductor structure, comprising:
a conductive pillar having a sidewall; and
a multi-layer isolation structure disposed on the sidewall of the conductive pillar and comprising N isolation layers, wherein N is one of a positive integer greater than or equal to 3, the isolation layers comprises a first isolation layer to a N^{th} isolation layer arranged sequentially along a direction away from the conductive pillar, a density of the first isolation layer is less than the densities of the other isolation layers of the isolation layers.

12. A method for manufacturing a semiconductor structure, comprising:
forming a stack structure; and
forming a multi-layer isolation structure in the stack structure, comprising:
forming a second isolation layer in the stack structure through a deposition process and an etching process; and
forming a first isolation layer on the second isolation layer through another deposition process.

13. The method according to claim 12, wherein the step of forming the second isolation layer in the stack structure comprises a thermal treatment.

14. The method according to claim 13, wherein the thermal treatment is performed before the etching process.

15. The method according to claim 12, wherein the thermal treatment is a rapid thermal process performed at 800-900° C. for about 25-35 seconds.

16. The method according to claim 12, wherein a density of the first isolation layer is different from a density of the second isolation layer.

17. The method according to claim 16, wherein the density of the first isolation layer is less than the density of the second isolation layer.

18. The method according to claim 12, wherein the stack structure comprises conductive layers and insulating layers stacked alternately;
wherein the step of forming the second isolation layer in the stack structure comprises forming the second isolation layer comprising recesses, the recesses correspond to the conductive layers.

19. The method according to claim 12, further comprising:
forming a lower conductive portion comprising a semiconductor material on the first isolation layer; and
forming an upper conductive portion comprises a metal material on the lower conductive portion.

20. The method according to claim 19, further comprising:
removing part of the first isolation layer and part of the second isolation layer before forming the lower conductive portion.
